(19) United States
(12) Patent Application Publication
(10) Pub. No.: US 2004/0084206 A1
(43) Pub. Date: May 6, 2004

(54) Fine pad pitch organic circuit board for flip chip joints and board to board solder joints and method

(76) Inventor: I-Chung Tung, Hsinchu (TW)

Correspondence Address: THE LAW OFFICES OF MIKIO ISHIMARU, 1110 SUNNYVALE-SARATOGA ROAD, SUITE A1, SUNNYVALE, CA, 94087, US

(21) Appl. No.: 10/289,996

(22) Filed: Nov. 6, 2002

(51) Int. Cl. H05K 1/03

(52) U.S. Cl. 174/255

(57) ABSTRACT

A fine pad pitch organic circuit board with plating solder and a method for fabricating the circuit board with plating solder are provided. The circuit board is formed with a plurality of densely arranged contact pads on at least a surface thereof in the absence of solder mask being applied over the surface. After deposition of a conductive seed layer on the contact pads, a resist layer is applied over the surface of the circuit board, and formed with a plurality of openings for exposing the seed layer corresponding in position to the contact pads. Then, a solder material is deposited in the openings by a plating method. Finally, the resist layer and the seed layer underneath the resist layer are removed, making the circuit board readily subject to subsequent fabrication processes for forming flip-chip joints or board-to-board joints.

### FIELD OF THE INVENTION

The present invention relates to a circuit board with plating solder for use in electronic packages and fabrication methods thereof, and more particularly, to an organic circuit board with plating solder on the fine pad pitch pads for forming flip-chip joints and board-to-board solder joints, and a method for fabricating the circuit board with plating solder on the fine pitch pads.

### BACKGROUND OF THE INVENTION

Since the introduction of the flip chip technology by IBM in the early 1960s, the flip chip devices have been mounted on an expensive ceramic substrate where the thermal expansion mismatch between the silicon chip and the ceramic substrate is less critical. In comparison with wire-bonding technology, the flip-chip technology is characterized by electrically connecting the chip to the substrate via solder bumps instead of bonding wires, and thereby provides significant benefits such as higher packaging density to facilitate reduction in device profile, higher electrical performances without having to use relatively long bonding wires, and so on. On this basis, the flip chip technology has been industrially practiced for the past 40 years using high-temperature solder (controlled-collapse chip connection, C4) on ceramic substrates. However, in recent years, driven by the demand of high-density, high-speed and low-cost semiconductor devices for the trend of miniaturization of modern electronic products, the flip chip devices mounted on a low-cost organic circuit board (e.g. printed circuit board or substrate) with an epoxy underfill to mitigate the thermal stress induced by the thermal expansion mismatch between the silicon chip and organic board structure have experienced an obviously explosive growth. This notable advent of low-temperature flip chip joints and organic-based circuit board has enabled the current industry to obtain inexpensive solutions for fabrication of flip chip devices.

In the current low-cost flip chip technology, the top surface of the semiconductor integrated circuit (IC) chip has an array of electrical contact pads. The organic circuit board has also a corresponding grid of contacts. The low-temperature solder bumps or other conductive adhesive material are placed and properly aligned in between the chip and circuit board. The chip is flipped upside down and mounted on the circuit board, in which the solder bumps or conductive adhesive material provide electrical input/output (I/O) and mechanical interconnects between the chip and circuit board. For solder bump joints, an organic underfill encapsulant may be further dispensed into the gap between the chip and circuit board to constrain the thermal mismatch and lower the stress on the solder joints.

A conventional flip-chip device 1 is illustrated in FIGS. 1A and 1B, wherein metal bumps and presolder bumps are combined to fabricate solder joints. As shown in the drawings, a plurality of metal bumps 11 are formed on the electrode pads 12 of a chip 13, and a plurality of presolder bumps 14 made of low-temperature solder are formed on contact pads 15 of an organic circuit board 16. Solder joints 17 are fabricated by reflowing the presolder bumps 14 to the corresponding metal bumps 11 at a temperature sufficient to melt and reflow the presolder bumps 14. Then, an underfill material 18 is applied into a gap between the chip 13 and the circuit board 16 to thereby encapsulate the solder joints 17. Thus, the fabrication of the flip-chip device 1 is completed. FIGS. 2A and 2B illustrate another example of a conventional flip-chip device 1′ without using presolder bumps. As shown in the drawings, a plurality of solder bumps 19 are formed on electrode pads 12 of a chip 13, and then, the chip 13 is reflowed to a circuit board 16 with the solder bumps 19 being bonded at contact pads 15 of the circuit board 16 to form solder joints 17. Finally, an underfill material 18 is used to fill a gap between the chip 13 and the circuit board 16 and to encapsulate the solder joints 17. Thus, the fabrication of the flip chip device 1′ is completed.

FIG. 3 illustrates a conventional organic circuit board 100 with the pad pitch 109 larger than 0.18 millimeter for flip chip packages generally contains contact pads 101 on its surface. An insulative layers 102 used for said organic circuit board 100 may be made of an organic material or a fiber-reinforced organic material or a particle-reinforced organic material, etc., for example, epoxy resin, polyimide, bismeleimide triazine, cyanate ester, polybenzocyclobutene, fluropolymer, or glass fiber composite thereof, etc. The contact pad 101 is formed typically from a metal material, such as copper. A popular metal barrier layer 103 includes an adhesive layer of nickel and a protective layer of gold may be formed to cover the pad 101. However, the barrier layer may also be made of gold, nickel, palladium, silver, tin, nickel/palladium, chromium/titanium, palladium/gold, or nickel/palladium/gold, etc., which can be made by electoplating, electroless plating, or physical vapor deposition, etc. An organic solder mask layer 104 is deposited on the surface of the circuit board 100 to protect the circuitry 105 and provide insulation. The top two circuit layers 105,106 are commonly interconnected through the electrically conductive via 107, which is well recognized in the art. As seen in FIG. 3, under such a large pad pitch 109 (e.g. larger than 0.18 millimeter) condition, a circuit line 108 can be placed in between two contact pads 101. Also, the presolder bumps 110 are intentionally made on the contact pads 101 for flip chip joints, in which the deposition of solder to form solder bumps is mainly formed by the stencil printing technology in the current industry. The commonly used method, the stencil printing technology, for forming presolder bumps on a circuit board can be referenced to related prior arts include U.S. Pat. No. 5,203,075 to Angulas et al, U.S. Pat. No. 5,492,266 to Hoebener et al, and U.S. Pat. No. 5,828,128 to Higashiguchi et al; to name just a few. However, in practice, the stencil-printing method becomes infeasible if a bump pitch 109 is decreased below 0.15 millimeter. In addition, with decreasing the bump pitch 109, the contact area 111 of the solder mask layer 104 to the body of said circuit board 100 would become smaller, which tends to weaken the adhesion of the solder mask layer 104 to the body of the circuit board 100.

This bump-pitch limitation can be overcome by employing electroplating technology in forming solder bumps, and prior arts involved in electroplating in forming solder bumps on a flip-chip circuit board include U.S. Pat. No. 5,391,514 to Gall et al and U.S. Pat. No. 5,480,835 to Hoebener et al. However, the electroplating process is defective at the risk of damaging a solder mask layer superficially applied over a circuit board, and also issues regarding uniformity of plating and bump height should be concerned. The presence of the solder mask layer also adversely affects performance of the circuit board, especially with a pad pitch being smaller than 0.15 mm; in this case, solder mask applied over the circuit board would become less adhesive to the circuit board (as discussed above with reference to FIG. 3), and may easily lose its insulation property due to metal corrosion and diffusion under an acute environment. Moreover, as the solder mask generally has relatively high CTE and low glass transition temperature compared to other materials used for constructing the organic circuit board, so that the presence of the solder mask layer at the area with fine-pitch pads on the circuit board may cause a reliability issue.

Therefore, in response to the above drawbacks, the problem to be solved herein is to provide a fine pad pitch organic circuit board without having solder mask being applied over the circuit board at the area with fine-pitch pads. Moreover, it is also desirable to provide an effective method to deposit solder on the pads of the circuit board for formation of flip-chip joints or board-to-board solder joints.

### SUMMARY OF THE INVENTION

A primary objective of the present invention is to provide a fine pad pitch circuit board and a method for fabricating the circuit board, without having to apply solder mask layer over fine pad pitch area of the circuit board, but with plating solder on its pads for forming flip chip joints and board to board solder joints.

In accordance with the above and other objectives, the present invention provides a method of forming plating solder on a fine pad pitch organic circuit board for making solder joints. In the method, there is provided a fine pad pitch organic circuit board including a surface bearing at least one contact pad with absence of any solder mask layer. Subsequently, a conductive seed layer is deposited over the board surface. A resist layer with at least an opening located at said pad is formed over said conductive seed layer. A solder material is then formed in the opening by a plating method. Finally, the resist and the metal seed layer beneath the resist are removed.

In accordance with the above and other objectives, the present invention provides a method of forming plating solder on a fine pad pitch organic circuit board for making solder joints. In the method, there is provided a fine pad pitch organic circuit board including a surface bearing at least one contact pad without presence of any solder mask layer. Subsequently, a resist layer with at least an opening located at said pad is formed over said conductive seed layer. A solder material is then formed in the opening by an electroless plating method. Finally, the resist is removed.

The above-fabricated circuit board with plating solder can be subsequently used for forming flip-chip joints with a chip, and for forming board-to-board joints with a circuit board. By virtue of no solder mask being applied over the area of the circuit board where the contact pads are densely arranged, the solder material can be successfully deposited on the contact pads by a plating process, without a reliability concern rendered by conventionally-used solder mask that may adversely affect performance of the circuit board.

### BRIEF DESCRIPTION OF THE DRAWINGS

The present invention can be more fully understood by reading the following detailed description of the preferred embodiments, with reference made to the accompanying drawings, wherein:

FIGS. 1A and 1B (PRIOR ART) are cross-sectional schematic diagrams showing fabrication processes for a conventional flip-chip device;

FIGS. 2A and 2B (PRIOR ART) are cross-sectional schematic diagrams showing fabrication processes for another conventional flip-chip device;

FIG. 3 (PRIOR ART) is a cross-sectional view of a conventional circuit board applied with solder mask;

FIGS. 4A and 4B are cross-sectional views respectively of a circuit board according to an embodiment of the invention;

FIGS. 5A and 5B are cross-sectional schematic diagrams showing a bump-fabricating process for the circuit board shown in FIG. 4A;

FIGS. 6A and 6B are cross-sectional schematic diagrams showing an embodiment of a bump-fabricating process for the circuit board shown in FIG. 4B;

FIGS. 7A and 7B are cross-sectional schematic diagrams showing another embodiment of a bump-fabricating process for the circuit board shown in FIG. 4B;

FIG. 8 is a cross-sectional view of a circuit board with contact pads thereof being coated by a catalyst layer according the invention;

FIGS. 9A and 9B are cross-sectional schematic diagrams showing a reflow-soldering process for forming flip-chip joints according an embodiment of the invention;

FIGS. 10A and 10B are cross-sectional schematic diagrams showing a reflow-soldering process for forming flip-chip joints according another embodiment of the invention;

FIGS. 11A and 11B are cross-sectional schematic diagrams showing a reflow-soldering process for forming flip-chip joints and board-to-board joints according to an embodiment of the invention;

FIGS. 12A to 12C are cross-sectional schematic diagrams showing a fabrication process for forming a flip-chip assembly through the use of solder-plating technology according to the invention;

FIGS. 12D and 12E are cross-sectional views respectively of a circuit board according to another embodiment of the invention;

FIG. 13A is a cross-sectional view of a circuit board according to a further embodiment of the invention;

FIG. 13B is a top view of the circuit board shown in FIG. 13A;

FIG. 13C is a cross-sectional view of a flip-chip assembly through the use of solder-plating plating for forming flip-chip joints according to the invention; and

FIGS. 13D and 13E are cross-sectional views respectively of a circuit board according to a further embodiment of the invention.

### DETAILED DESCRIPTION OF THE PREFERRED EMBODIMENTS

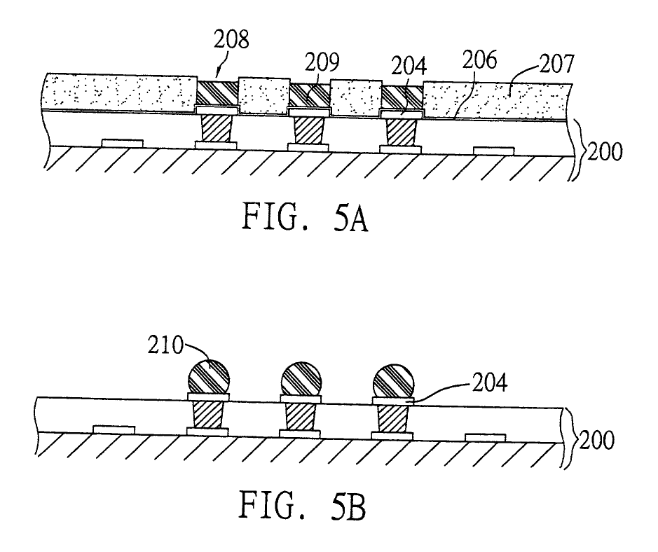

The preferred embodiment of a fine pad pitch organic circuit board and a fabrication method thereof proposed in the present invention are described in detail as follows with reference to FIGS. 4 to 13.

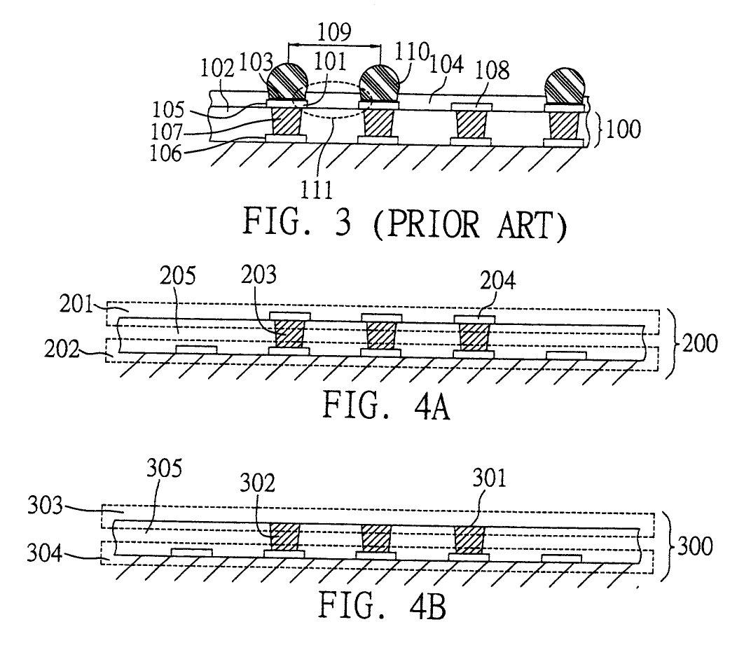

In response to the previously discussed problem regarding provision of solder mask over a conventional circuit board rendering a reliability issue and making a stencil-printing process infeasible to be implemented with reference to FIG. 3, the invention is thus directed to a fine pad pitch organic circuit board without the use of solder mask and a plating process for placing solder on the surface pads, so as to eliminate those solder-mask induced drawbacks. As shown in FIG. 4A, a circuit board 200 with the top two circuit layers 201, 202 are electrically interconnected by a conductive via 203. However, on the surface circuit layer 201 only contains contact pads 204 but there is no other metal traces present. A metal barrier layer made of gold, nickel, palladium, silver, tin, gold/nickel, nickel/palladium, or gold/palladium/nickel etc. may be formed on said contact pads 204 if necessary. An insulative layers 205 used for said organic circuit board 100 may be made of an organic material or a fiber-reinforced organic material or a particle-reinforced organic material, etc., for example, epoxy resin, polyimide, bismeleimide triazine, cyanate ester, polybenzocyclobutene, or glass fiber composite thereof, etc. Alternatively, as shown in FIG. 4B, an organic circuit board 300 is also designed only containing contact pads 301 on its surface, which exactly is the top surface of the conductive via 302. A metal barrier layer made of gold, nickel, palladium, silver, tin, gold/nickel, nickel/palladium, or gold/palladium/nickel etc. may be formed on said contact pads 301. The top two circuit layers 303,304 are interconnected through said conductive via 302. An insulative layer 305 in between said top two circuit layers 303,304 may be made of an organic material or a fiber-reinforced organic material or a particle-reinforced organic material, etc., for example, epoxy resin, polyimide, bismeleimide triazine, cyanate ester, polybenzocyclobutene, fluropolymer, or glass fiber composite thereof, etc. Similarly, there is no provision of solder mask over the surface of said circuit board 300.

For depositing solder on said contact pads 204, 301 of said circuit board 200, 300, a plating method, i.e. electroplating or electroless plating, can be utilized in the case of said contact pads 204, 301 being arranged in high density or with fine pitches. Before depositing solder on said contact pads 204, 301, a conductive seed layer (described in more detail hereinafter) is directly applied over the surface of said circuit board 200, 300 where said contact pads 204, 301 are formed, and this conductive seed layer facilitates subsequent solder deposition. Coating of the conductive seed layer can be carried out by physical vapor deposition (PVD), chemical vapor deposition (CVD), electroless plating or chemical precipitation, such as sputtering, evaporation, arc vapor deposition, ion beam sputtering, laser ablation deposition, plasma enhanced CVD, or metallorganic CVD, etc.

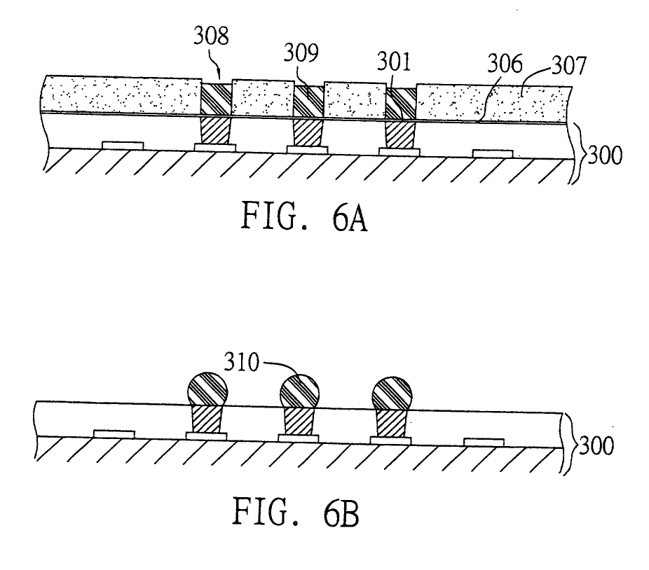

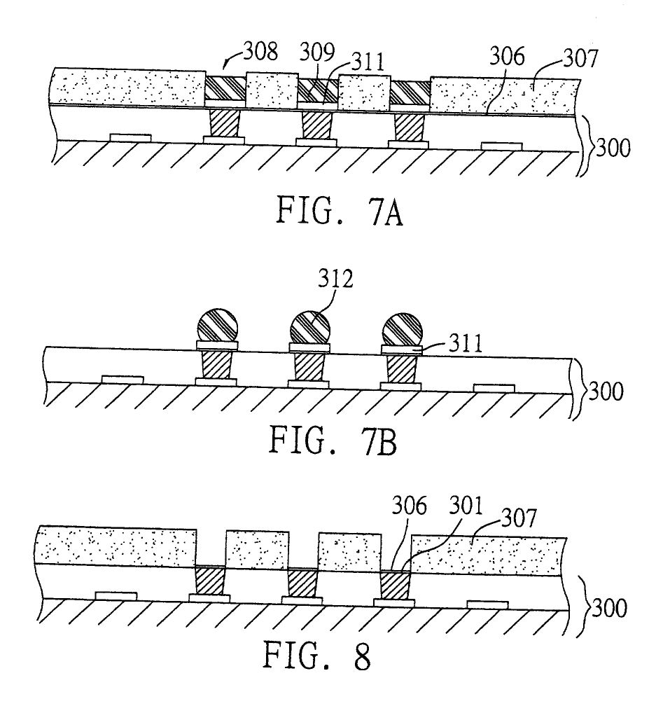

As shown FIG. 5A with respect to said circuit board 200, a conductive seed layer 206 is deposited over the surface of said circuit board 200 where said contact pads 204 are disposed. A resist layer 207 is applied over said seed layer 206, and formed with a plurality of openings 208 corresponding in position to said contact pads 204 to thereby partly expose the seed layer 206. Subsequently, a solder material 209 is deposited in said openings 208 on the exposed part of said seed layer 206 by a plating process (preferably electroplating). Then, as shown in 5B, said resist layer 207 and said seed layer 206 covered by said resist layer 207 are removed. Finally, a reflow-soldering process is performed at a temperature sufficient to melt and reflow said deposited solder material 209, whereby said solder material 209 are reflowed to form solder bumps 210 on said contact pads 204. Similarly, in respect of said circuit board 300, as shown in FIG. 6A, a conductive seed layer 306 is deposited on the surface of said circuit board 300 where said contact pads 301 are situated. A resist layer 307 is applied over said seed layer 306 and formed with a plurality of openings 308 corresponding in position to said contact pads 301 to thereby partly expose said seed layer 306. Subsequently, a solder material 309 is deposited in said opening 308 by a plating process. Then, as shown in FIG. 6B, said resist layer 307 and said seed layer 306 underneath said resist layer 307 are removed, allowing a reflow-soldering process to be performed to reflow said deposited solder material 309 and to thereby form the solder bumps 310 on said contact pads 301.

According to the present invention, said seed layer 206, 306 may be made of a metal or an alloy or a stacking of several metal layers. However, according to our practical experiences, said conductive seed layer 206,306 is preferably made of copper or palladium particles (especially for electroless plating). Said solder material 209, 309 may be an alloy made by the mixture of the elements selected from the group consisting of lead, tin, silver, copper, bismuth, antimony, zinc, nickel, aluminum, magnesium, indium, tellurium and gallium, etc. It should be noted here that the conductive traces may also be made in between said contact pads if necessary or possible.

According to the present invention, said solder material 209,309 can also be formed in a way that its elements are deposited in sequence by plating. For instance, a thin layer of silver and then a layer of tin can be deposited by plating in sequence in said openings 208,308. After a reflow process, silver is dissolved in tin finally to form eutectic tin-silver solder bumps 210,310.

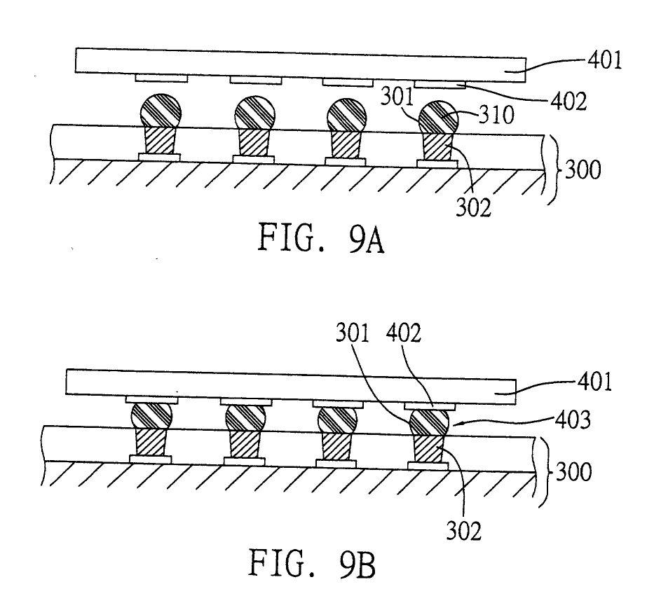

In another embodiment of the invention, prior to deposition of said solder material 209, 309, a metal pad can be used to elevate said solder material 209, 309 in position deposited subsequently thereon. As shown in FIG. 7A, for example of said circuit board 300, after applying said resist layer 307, a plurality of metal pads 311 are formed by electroplating or electroless plating on the exposed part of said seed layer 306 respectively corresponding in position to said contact pads 301. Such said metal pad 311 may be composed of a single metal layer or multiple metal layers, and preferably made of copper or a high-temperature solder material such as SnPb, SnAg or SnCu alloy, etc. Then, said solder material 309 is deposited on each of said metal pads 311, and subjected to a reflow-soldering process for forming the resulting solder bumps 312 on said metal pads 311, as shown in FIG. 7B.

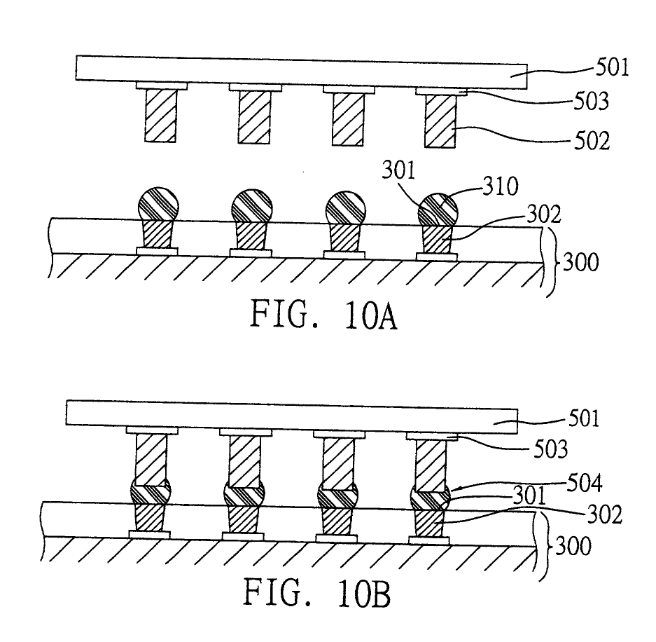

As shown in FIG. 8, said seed layer 306 may be selectively formed on the contact pads 301 instead of the entire surface of said circuit board 300; with provision of said resist layer 307, which allows a solder material (not shown) to be directly deposited over said seed layer 306 by electroless plating. In such a case, said seed layer 306 actually serves as a catalyst layer for the electroless plating process. However, without presence of said catalyst layer (i.e. seed layer) 306, said solder material 309 can also be deposited on said contact pads 301 directly by an electroless plating process. In such a case, said solder material 209,309 can thus be deposited in said openings 208,308 of said resist layer 207,307 with absence of said seed layer 206,306 by means of an electroless plating method.

Said seed layer 206, 306 on said circuit board 200, 300 is preferably thinner for easy removal by using an etching method. In practice, said seed layer 206, 306 works well with a thickness of 0.0001 to 0.001 millimeter. Also, the etching solution can be selected with reference to well-known metallography books, for example, “Metallographic etching”, Gunter Petzow, American Society for Metals, Metals Park, Ohio (1978). Moreover, said conductive vias 203, 302 may be well known plated through-holes, or vias filled or partially filled with a conductive material, such as copper, solder alloy, metal filled resin, or carbon filled resin, etc., to elicit electrical conductivity of the conductive vias 203, 302. Especially, when the composition of said conductive material is the same as that of said plating solder 209,309, said conductive via 203,302 and plating solder can be made at the same plating step. Furthermore, said insulaive layer 205, 305 may be surface-roughened chemically or physically if necessary, to improve adhesion properties in the subsequent packaging processes.

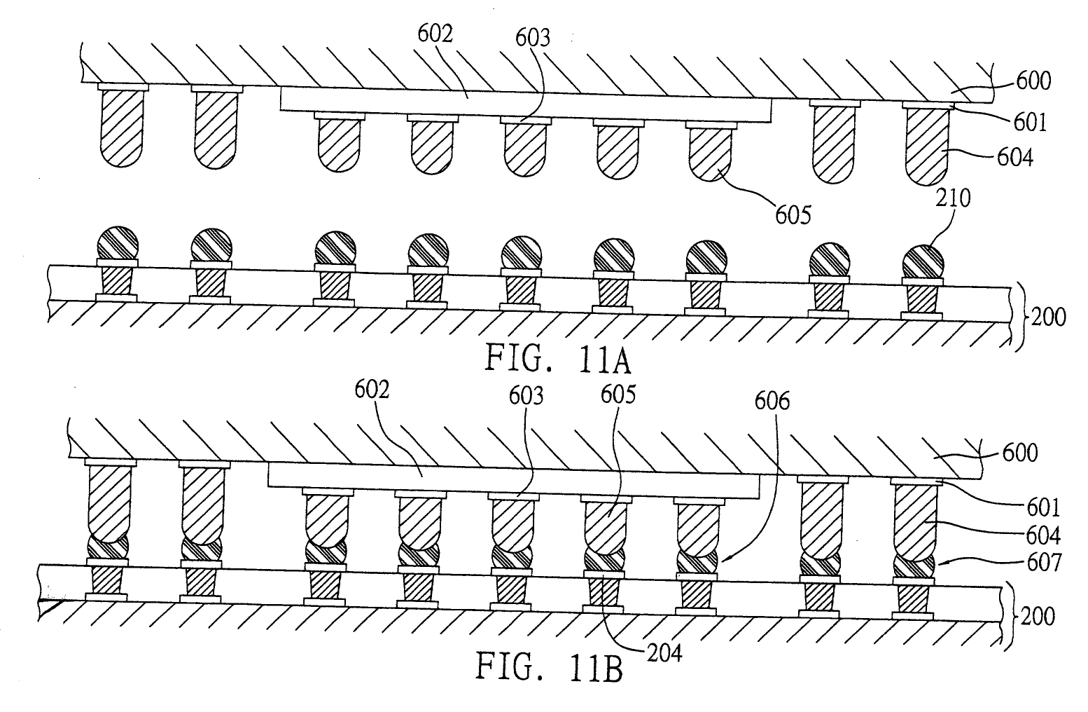

Said fabricated solder bumps 310 on said contact pads 301 of said circuit board 300 can be readily applied to formation of flip-chip joints, as shown in FIG. 9A. A semiconductor chip 401 formed with a plurality of electrode pads 402 is prepared and mounted to said circuit board 300 in a manner that said electrode pads 402 correspond in position respectively to said solder bumps 310 on said circuit board 300. Then, as shown in FIG. 9B, a reflow-soldering process is performed to reflow said solder bumps 310 onto said electrode pads 402 and thereby form a plurality of flip-chip joints 403 that are interposed between said chip 401 and said circuit board 300, which electrically connecting said chip 401 to said circuit board 300.

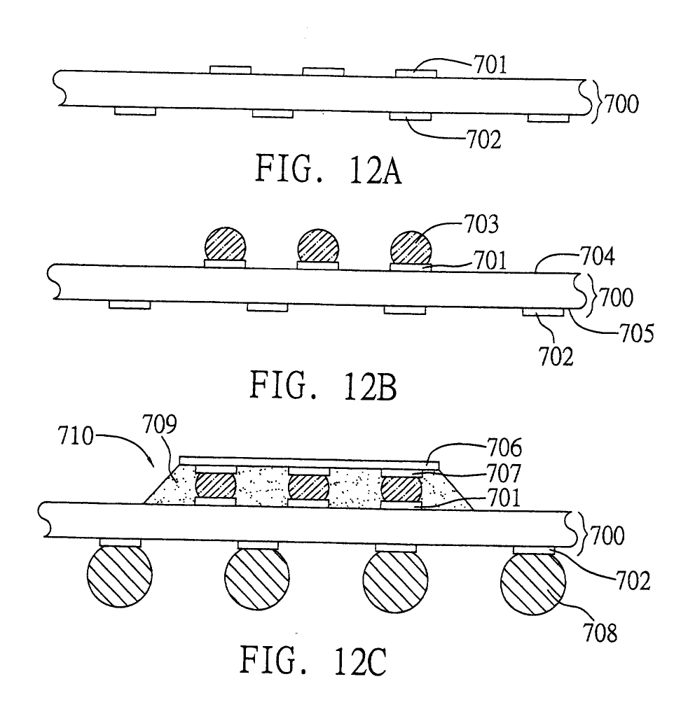

In another embodiment, said circuit board 300 with said solder bumps 310 can be applied to a semiconductor chip with metal bumps for forming flip-chip joints. As shown in FIG. 10A, a chip 501 formed with a plurality of metal bumps 502 respectively on the electrode pads 503 is mounted to said circuit board 300 in a manner that said metal bumps 502 correspond in position respectively to said solder bumps 310 on said circuit board 300. Then, as shown in FIG. 10B, said solder bumps 310 are reflowed onto said metal bumps 502 to form the flip-chip joints 504 between said chip 501 and said circuit board 300. According to the present invention, said metal bumps 502 can be made of a metal or an alloy or a stacking of several metals, such as solder bumps, gold bumps, copper bumps, copper bumps, or copper posts covered with solder caps, etc., and can be any shape, such as stud bumps, ball bumps, columnar bumps, or others.

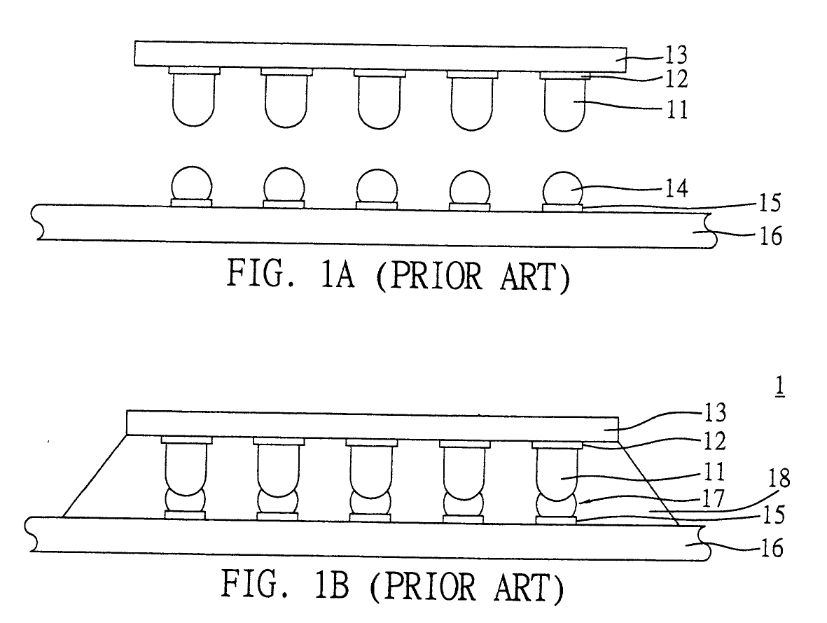

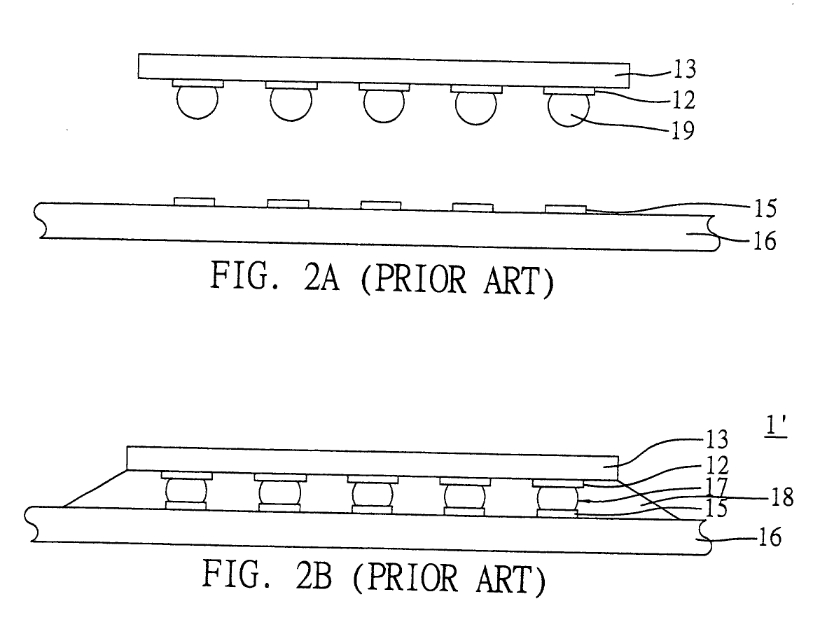

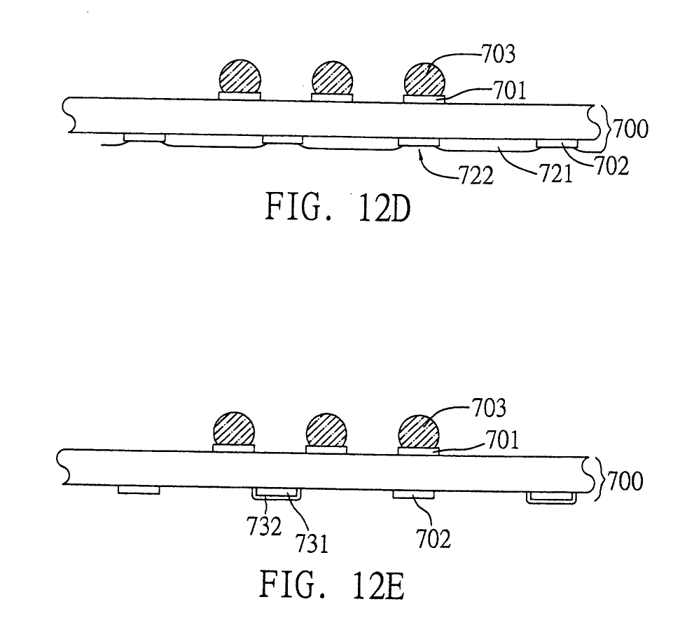

The circuit board according to the invention can be further used for forming flip-chip joints and board-to-board solder joints simultaneously; in this embodiment, said circuit board 200 formed with said solder bumps 210 is exemplified. As shown in FIG. 11A, a circuit board 600 (hereinafter referred to as “second circuit board”), which can be an organic or ceramic circuit board, is prepared and mounted a chip 602 approximately at a central position, and a plurality of contact pads 601 are formed on said second circuit board 600 around said chip 602, wherein a plurality of metal bumps 604, 605 are respectively implanted on electrode pads 603 of said chip 602 and on said contact pads 601 of said second circuit board 600. Then, said second circuit board 600 is mounted to said circuit board 200 (hereinafter referred to as “first circuit board”) according to the invention in a manner as to face said metal bumps 604, 605 toward said solder bumps 210 formed on said first circuit board 200. As shown in FIG. 1B, a reflow-soldering process is carried out by which said metal bumps 605 are reflowed onto said corresponding solder bumps 210 to form flip-chip joints 606 between said chip 602 and said first circuit board 200, and said solder bumps 210 are reflowed onto the corresponding metal bumps 604 to form the board-to-board joints 607 between said second circuit board 600 and said first circuit board 200. According to the present invention, said metal bumps 604,605 can be made of a metal or an alloy or a stacking of several metals, such as solder bumps, gold bumps, copper bumps, copper bumps, or copper posts covered with solder caps, etc., and can be any shape, such as stud bumps, ball bumps, columnar bumps, or others.

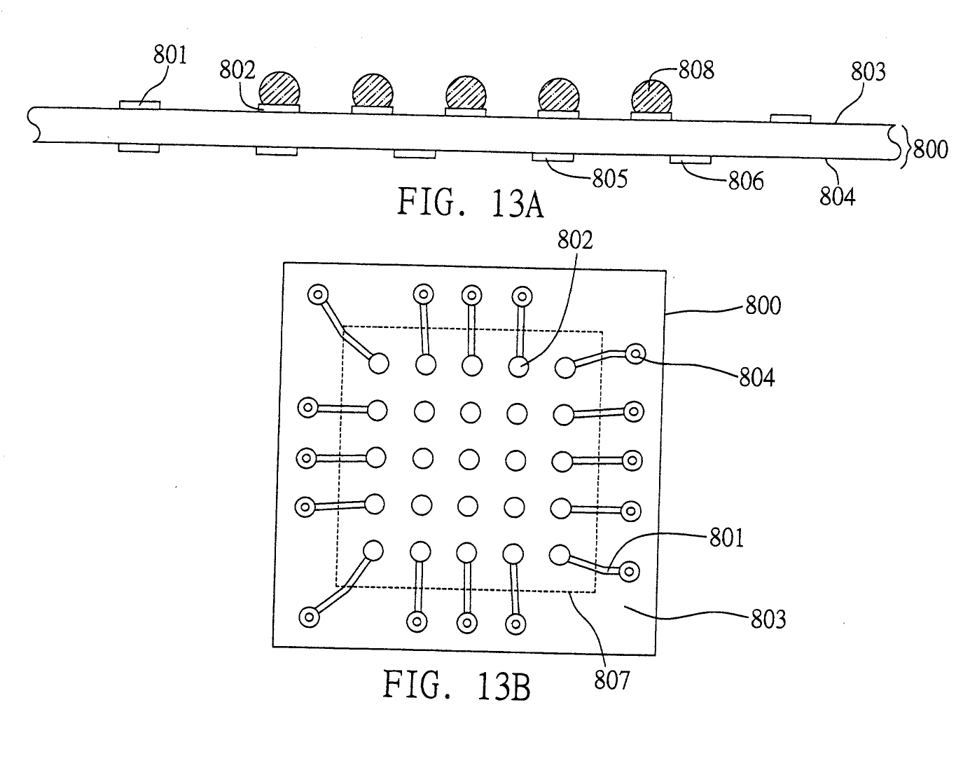

Now referring to FIG. 12A, an organic circuit board 700 according to the invention, which can be made by fabrication processes similar to said circuit board 200 shown in FIG. 4A, is used as a substrate or a chip carrier for producing a flip-chip assembly 710 (as shown in FIG. 12C). Said circuit board 700 is similarly fabricated without using solder mask, and is formed with a plurality of contact pads 701, 702 respectively on both sides thereof. Then, referring to FIG. 12B, a plurality of solder bumps 703 are formed by the plating method on said contact pads 701. Referring to FIG. 12C, a chip 706 is mounted on said circuit board 700 in a flip-chip manner that the electrode pads 707 formed on said chip 706 are attached to said solder bumps 703. Subsequently, an underfill material 709 is applied to fill a gap between said chip 706 and said circuit board 700. After that, a plurality of external terminals 708, such as solder balls (as illustrated in the drawing), pins or metal post, etc., are implanted at said contact pads 702 of said circuit board 700, Thus the fabrication of the flip-chip assembly 710 is completed.

Alternatively, as shown in FIG. 12D, said circuit board 700 can be applied with a solder mask layer 721 on a surface where said contact pads 702 are situated, and said solder mask layer 721 is formed with a plurality of openings 722 corresponding in position to the contact pads 702 to thereby expose the contact pads 702 for subsequent implantation of external terminals (not shown). Further, as shown in FIG. 12E, conductive traces 731 can be formed on the same surface of said circuit board 700 with the contact pads 702, and a surface coating 732, such as gold, nickel/gold, or epoxy resin etc., may be made on each of said conductive traces 731 for corrosion protection.

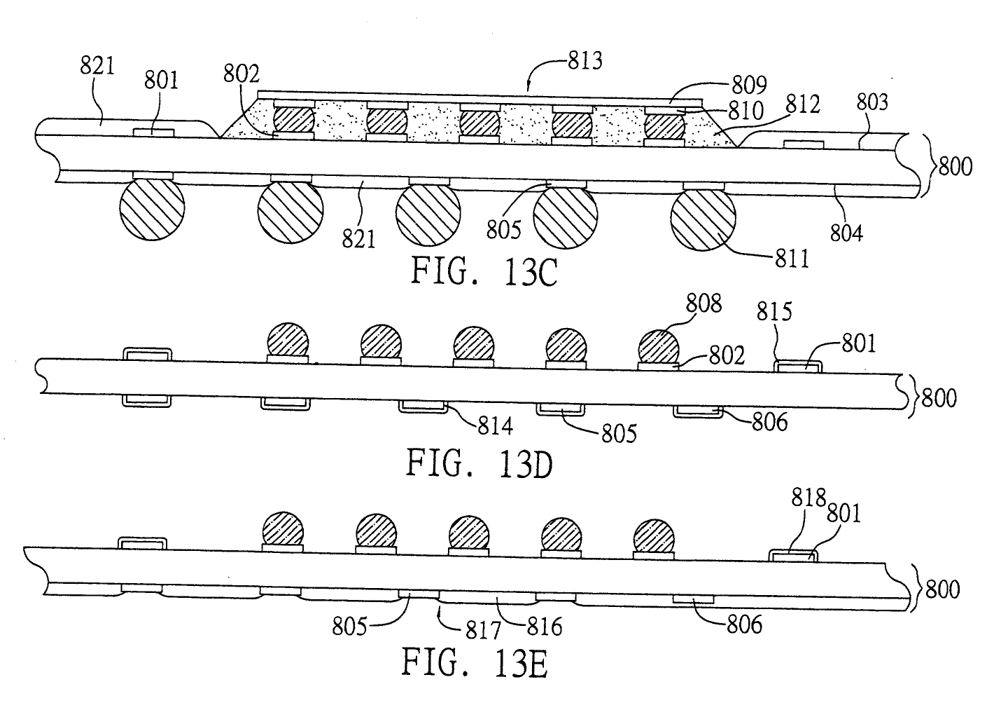

Referring to FIG. 13A, an organic circuit board 800, which can be made by fabrication processes similar to said circuit board 200 shown in FIG. 4A, is used as a substrate or a chip carrier for producing a flip-chip assembly 813 (as shown in FIG. 13C). Said circuit board 800 is similarly fabricated without using solder mask, and is formed with conductive traces 801 and contact pads 802 on an upper surface 803 thereof and with contact pads 805 and with presence or absence of conductive traces 806 on a lower surface 804 of said circuit board 800. Referring to FIG. 13B, as a pad pitch between said adjacent contact pads 802 on said upper surface 803 is considerably small (e.g. at least smaller than 0.15 millimeter), said conductive traces 801 are not capable of going through the pitch space between said adjacent contact pads 802, and thus said conductive traces 801 are primarily connected to said contact pads 802 located peripherally in a bump area encompassed by the dotted line 807. Referring back to FIG. 13A, a plurality of solder bumps 808 are then formed on said contact pads 802 on said upper surface 803 of said circuit board 800 for subsequent fabrication processes.

As shown in FIG. 13C, a solder mask layer 821 can also be applied over said upper and lower surfaces 803, 804 of said circuit board 800 to cover said conductive traces 801, 806 but expose said contact pads 802 and the bump area (the area enclosed by said dotted line 807, as shown in FIG. 13B). Then, a chip 809 with electrode pads 810 is mounted to said circuit board 800, and an underfill material 812 is applied to fill a gap between said chip 809 and said circuit board 800. Finally, external terminals 811 such as solder balls, pins, or metal post, etc., are attached to said contact pads 805 on said lower surface 804 of said circuit board 800. Thus, the fabrication of the flip-chip assembly 813 is completed. Alternatively, as shown in FIG. 13D, a surface coating 814, such as gold, nickel/gold, or organic solderability preservative (OSP), etc., may be formed on each of said contact pads 805, and a surface coating 815, such as gold, nickel/gold, or epoxy resin, etc., may be formed on said conductive traces 801,806 for protection purposes. Moreover, as an alternative, as shown in FIG. 13E, a surface coating 818, such as OSP, epoxy resin, gold, nickel/gold, etc., may also be made on each of said conductive traces 801 on said upper surface 803 of said circuit board 800, and a solder mask layer 816 can be applied over said lower surface 804 of said circuit board 800 to cover said conductive traces 806 but expose said contact pads 805 via a plurality of openings 817 formed through the solder mask layer 816.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

1. A fine pad pitch organic circuit board with plating solder comprising:
at least one surface adapted to receive solder joints;
at least one contact pad and with absence of any solder mask layer formed on said surface;
a plating solder deposited on said contact pad.

2. The fine pad pitch organic circuit board with plating solder of claim 1 wherein said plating solder is a solder made by electroplating.

3. The fine pad pitch organic circuit board with plating solder of claim 1 wherein said plating solder is a solder made by electroless plating.

4. The fine pad pitch organic circuit board with plating solder of claim 1 wherein said plating solder is a solder made by a combination of electroplating and electroless plating methods.

5. The fine pad pitch organic circuit board with plating solder of claim 1 wherein there is not any conductive trace on said board surface.

6. A fine pad pitch organic circuit board with plating solder comprising:
at least one surface adapted to receive solder joints;
at least two contact pads formed on said surface but with absence of any solder mask layer and conductive trace formed in between said two contact pads;
a plating solder deposited on said two contact pads.

7. The fine pad pitch organic circuit board with plating solder of claim 6 wherein said plating solder is a solder made by electroplating.

8. The fine pad pitch organic circuit board with plating solder of claim 6 wherein said plating solder is a solder made by electroless plating.

9. The fine pad pitch organic circuit board with plating solder of claim 6 wherein said plating solder is a solder made by a combination of electroplating and electroless plating methods.

10. A method of forming a fine pad pitch organic circuit board with plating solder, the method comprising:
providing an organic circuit board including a surface bearing at least one contact pad and with absence of any solder mask layer on said surface;
forming a conductive layer over said board surface;
depositing a resist layer with at least one opening located at said pad over said conductive layer;
depositing a solder material in said opening by a plating method;
removing said resist layer and said conductive layer beneath said resist layer.

11. The method of claim 10, wherein said conductive layer is made of metal selected from the group of copper, tin, and tin-lead alloy.

12. The method of claim 10, wherein said conductive layer is a form of multilayer structure made of metals selected from the group of copper, tin, nickel, chromium, titanium, copper-chromium alloy, and tin-lead alloy.

13. The method of claim 10, wherein said solder material is an alloy made by the mixture of the elements selected from the group consisting of lead, tin, silver, copper, bismuth, antimony, zinc, nickel, aluminum, magnesium, indium, tellurium, and gallium.

14. The method of claim 10, wherein said plating method is an electroplating method.

15. The method of claim 10, wherein said plating method is an electroless plating method.

16. The method of claim 10, wherein said plating method is a combination of electroplating and electroless plating methods.

17 The method of claim 10, a metal pad is made on said contact pad before the deposition of said solder material.

18. A method of forming plating solder on a fine pad pitch organic circuit board with plating solder, the method comprising:
providing an organic circuit board including a surface bearing at least two contact pads and with absence of any solder mask layer and conductive trace formed in between said two contact pads;
forming a conductive layer over said board surface;
depositing a resist layer with at least two openings located at said pads over said conductive layer;
depositing a solder material in said openings by a plating method;
removing said resist layer and said conductive layer beneath said resist layer.

19. The method of claim 18, wherein said conductive layer is made of metal selected from the group of copper, tin, and tin-lead alloy.

20. The method of claim 18, wherein said conductive layer is a form of multilayer structure made of metals selected from the group of copper, tin, nickel, chromium, titanium, copper-chromium alloy, and tin-lead alloy.

21. The method of claim 18, wherein said solder material is an alloy made by the mixture of the elements selected from the group consisting of lead, tin, silver, copper, bismuth, antimony, zinc, nickel, aluminum, magnesium, indium, tellurium, and gallium.

22. The method of claim 18, wherein said plating method is an electroplating method.

23. The method of claim 18, wherein said plating method is an electroless plating method.

24. The method of claim 18, wherein said plating method is a combination of electroplating and electroless plating methods.

25. The method of claim 18, wherein a metal pad is made before the deposition of said solder material.

26. A method of forming a fine pad pitch organic circuit board with plating solder, the method comprising:
providing an organic circuit board including a surface bearing at least one contact pad and with absence of any solder mask layer on said surface;
depositing a resist layer with at least one opening located at said pad over said surface;
depositing a solder material in said opening by an electroless plating method;
removing said resist layer.

27. The method of claim 26, wherein said solder material is an alloy made by the mixture of the elements selected from the group consisting of lead, tin, silver, copper, bismuth, antimony, zinc, nickel, aluminum, magnesium, indium, tellurium, and gallium.

28. The method of claim 26, a catalytic layer is deposited in said opening before the deposition of said solder material.

29. The method of claim 28, wherein said catalytic layer is formed by palladium particles.

30. A method of forming plating solder on a fine pad pitch organic circuit board with plating solder, comprising:
providing an organic circuit board including a surface bearing at least two contact pads and with absence of any solder mask layer and conductive trace formed in between said two contact pads;
depositing a resist layer with at least two openings located at said pads over said surface;
depositing a solder material in said openings by an electroless plating method;
removing said resist layer.

31. The method of claim 30, wherein said solder material is an alloy made by the mixture of the elements selected from the group consisting of lead, tin, silver, copper, bismuth, antimony, zinc, nickel, aluminum, magnesium, indium, tellurium, and gallium.

32. The method of claim 30, a catalytic layer is deposited in said opening before the deposition of said solder material.

33. The method of claim 32, wherein said catalytic layer is formed by palladium particles.
